(19) United States
(12) Patent Application Publication
(10) Pub. No.: US 2006/0258327 A1
(43) Pub. Date: Nov. 16, 2006

(54) Organic based dielectric materials and methods for minaturized RF components, and low temperature coefficient of permittivity composite devices having tailored filler materials

(76) Inventors: Baik-Woo Lee, Atlanta, GA (US); Markondeya Raj Pulugurtha, Atlanta, GA (US); Chong Yoon, Roswell, GA (US); Rao Tummala, Stone Mountain, GA (US); Isaac R. Abothu, Atlanta, GA (US); Swapan K. Bhattacharya, Cumming, GA (US)

Correspondence Address: Law Offices of Kenneth W. Float, 2095 Hwy. 211 NNW, #2F, Braselton, GA, 30517, US

(21) Appl. No.: 11/429,780

(22) Filed: May 8, 2006

Related U.S. Application Data
(60) Provisional application No. 60/679,909, filed on May 11, 2005.
(60) Provisional application No. 60/679,809, filed on May 11, 2005.

(51) Int. Cl. H04B 1/06; H01L 21/00

(52) U.S. Cl. 455/352; 438/1

(57) ABSTRACT

Disclosed are composite RF devices having low temperature coefficient of permittivity (TCP) and methods for fabricating same. The RF devices comprise first and second conductive electrodes with a composite dielectric material disposed there between that comprises a polymer material having positive or negative TCP and one or more ceramic filler materials having corresponding negative or positive temperature coefficients of permittivity. The composite dielectric material may also comprise a blend of positive and negative TCP ceramic filler materials. The composite dielectric material may also have a bimodal distribution of positive and negative TCP filler materials to vary the packing density of the dielectric material. Various devices may be fabricated including thin and thick film capacitors and antennas, which may be formed on or within an organic layer, silicon material, ceramic material, ceramic composite material or insulating material.

### STATEMENT REGARDING FEDERALLY SPONSORED RESEARCH OR DEVELOPMENT

This invention was made with Government support under Agreement No. EEC-9402723 awarded by the National Science Foundation. The U.S. Government may have a paid-up license in this invention and the right in limited circumstances to require the patent owner to license to others on reasonable terms as provided for by the terms of the Agreement.

### BACKGROUND

The present invention relates generally to organic based dielectric materials and methods for use in fabricating miniaturized RF components. The present invention also relates to composite capacitors and other RF devices having a low temperature coefficient of permittivity (TCP) that are achieved by tailoring dielectric filler materials.

Important design parameters such as impedance and resonant frequency, for example, need to be accurately controlled to provide the best RF performance. To achieve an efficient design, almost all wireless communication systems need components (capacitors, resistors, antennas, etc.) with very high tolerance and stable properties with temperature and humidity. While the industry is moving towards complete RF system integration using thin film embedded components, embedding high performance (low loss, low TCP) capacitors in large-area organic packaging using low cost processing methods is one of the toughest challenges that the packaging industry is now facing. Currently, there is no material that can be used to embed high performance low loss, low TCP and high permittivity polymers for large-area organic packaging using low cost processing methods. These materials are critical for miniaturizing antennas and capacitors for mixed signal circuits. The same materials are also ideally suitable for miniaturizing antennas. The best material for organic compatible antenna today is liquid crystal polymer (LCP) despite its low permittivity because of its low loss and TCP.

The range of capacitance values depends on the application and varies from few pF to nF. For many applications, the capacitance value has to be stable within 0.2% over a 100° C. temperature range. This typically translates to about 20 ppm/° C. of TCP. Several solutions exist that have been patented for thermally stable RF LTCC capacitors, but for emerging organic RF packaging applications, there is a limited availability of organically-compatible high permittivity and low loss materials that have good thermal stability.

The best solution for a miniaturized RF capacitor is a polymer-ceramic composite, where the polymer enables low-temperature large-area processing while the ceramic filler increases the permittivity of the composite. Composite research to date has been based on epoxies and ferroelectrics such as BaTiO₃, which have very high TCP and loss. Epoxy-BaTiO₃ composites cannot achieve loss <0.01 or TCP within 100 ppm/° C. Therefore, none of the currently available composite capacitors are suitable for high performance RF capacitor requirements. Low TCP fillers and low loss polymer matrix composites are essential to develop capacitors for low cost RF applications.

U.S. Pat. No. 5,739,193 entitled “Polymeric compositions having a temperature-stable dielectric constant” discloses in it Summary of the Invention section, for example, a “polymeric composition which has a high dielectric constant with a low temperature coefficient is made from a thermoplastic polymer, a high dielectric ceramic having a dielectric constant of at least about 50 at 1.0 GHz and 20° C., and a second ceramic material which has a dielectric constant of at least about 5.0 at 1.0 GHz and 20° C. The high dielectric ceramic and the second ceramic material have temperature coefficients that are opposite in sign from one another. In other words, the dielectric constant of either the high dielectric ceramic or the second ceramic material increases with increasing temperature, while the dielectric constant of the other of the high dielectric ceramic and the second ceramic material decreases with increasing temperature. Thus, the changes in dielectric constant with temperature tend to offset one another, and the temperature coefficient (i.e. the temperature dependence of the dielectric constant) of the composite is reduced. The use of this method is sometimes referred to hereafter as “temperature compensation”. In general, the fillers are used to raise the dielectric constant of the plastic, so that the dielectric constant of the composition is at least about 4.0 at 1.0 GHz and 20° C.”

However, US. Pat. No. 5,739,193 does not disclose or suggest anything regarding temperature compensation between polymer and ceramic fillers. The requirements of TCP in RF electronic devices cannot be satisfied without considering temperature dependency of polymer's permittivity. The present invention not only address the temperature compensation between polymer and ceramic fillers but also include chemical or structural modification of ceramic fillers for the precise and easy temperature compensation with various polymers having different TCP such as modification of ceramic fillers with dopants and use of core-shell structure for the ceramic fillers.

### BRIEF DESCRIPTION OF THE DRAWINGS

The various features and advantages of the present invention may be more readily understood with reference to the following detailed description taken in conjunction with the accompanying drawings, wherein like reference numerals designate like structural elements, and in which:

FIG. 1 is a graph that illustrates change in capacitance versus temperature that demonstrates the capabilities of the approaches disclosed herein;

FIG. 2 is a graph that illustrates permittivity versus temperature for an exemplary composite dielectric comprising both positive and negative TCP materials;

FIG. 3 illustrates an exemplary ceramic-polymer composite capacitor;

FIG. 4 illustrates an exemplary ceramic-ceramic-polymer composite capacitor;

FIG. 5 illustrates an exemplary core-shell-polymer composite capacitor;

FIG. 6 illustrates a unimodal distribution of two filler particles;

FIG. 7 illustrates a bimodal distribution of two filler particles; and

FIG. 8 illustrates exemplary methods of fabricating a composite capacitor.

### DETAILED DESCRIPTION

High permittivity materials invariably exhibit high temperature coefficient of permittivity (TCP). However, these materials show positive or negative TCP depending on their structure and polarization behavior. The approaches disclosed herein overcome this fundamental material limitation by choosing filler materials having appropriate positive or negative TCP to construct a dielectric material used in a composite device, and which make the net TCP of the composite device close to zero. This provides for a composite device having a low temperature drift.

Approaches are disclosed herein wherein low loss and low TCP are achieved with at least a two-times improvement in permittivity leading to significant size reductions in RF devices. Using the disclosed approaches and formulations, much higher permittivity can be obtained leading to a reduction in antenna size, for example. These materials are also suitable for miniaturizing other resonating structures such as electronic band gap (EBG) structures where size is dependent on the wavelength of the propagating electromagnetic wave.

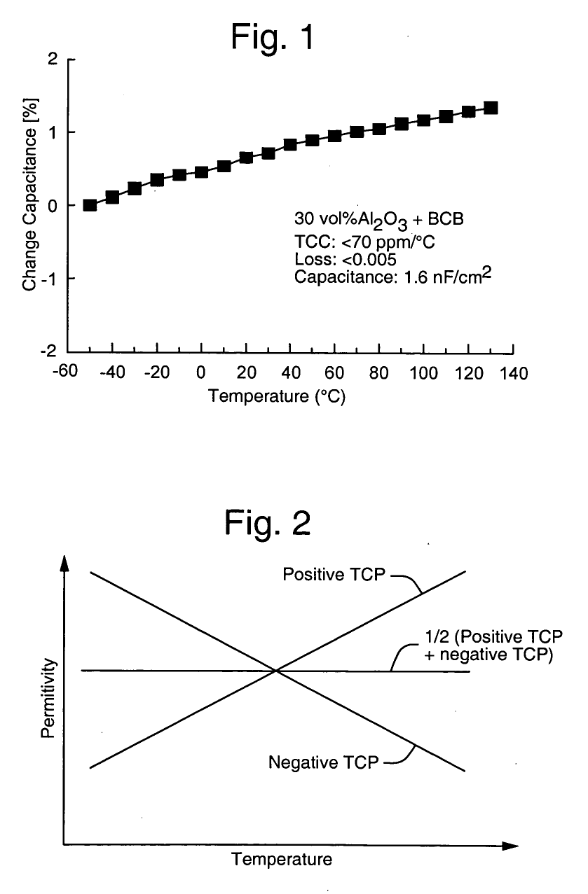

Polymers and filler materials show positive or negative TCP depending on their structure and chemistry. By choosing filler materials that have opposite TCP behavior to the polymer, the net TCP can be modulated to vary within a target permittivity range. FIG. 1 is a graph that illustrates change in capacitance versus temperature for an exemplary composite device, comprising a composite capacitor that demonstrates the capabilities of the approaches disclosed herein. Representative examples are discussed below. FIG. 2 is a graph that illustrates permittivity versus temperature for an exemplary composite capacitor comprising both positive and negative TCP materials, and illustrates that blending appropriate positive and negative TCP materials to form a dielectric material having a low TCP, thus providing a stable, low temperature drift device. Depending on the temperature range and the filler materials that are used, the composite device (capacitor) may be designed to have any desired TCP.

Ceramic-Polymer Composite

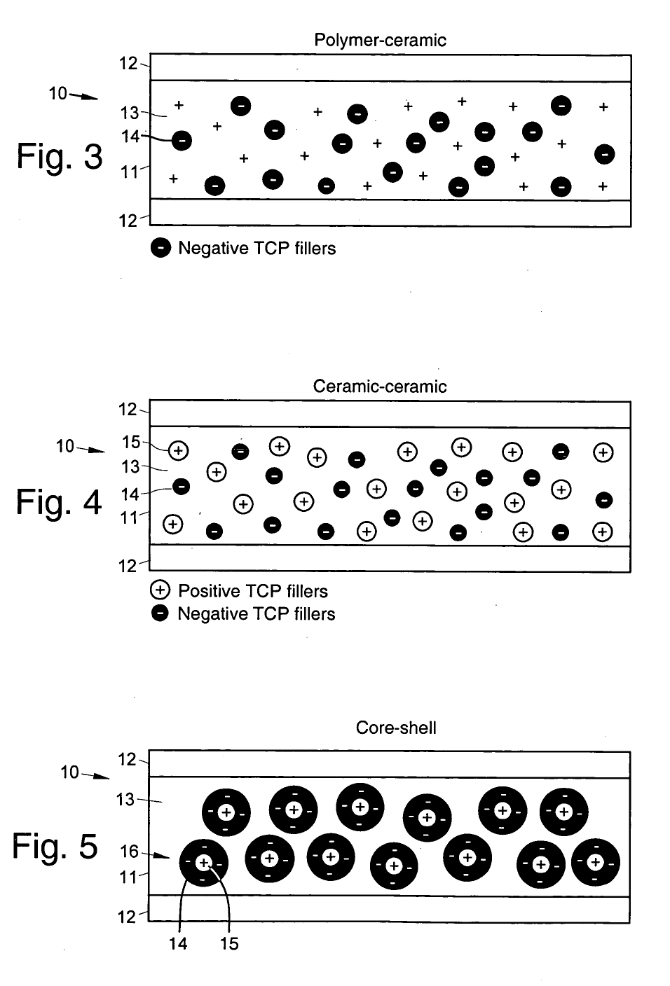

FIG. 3 illustrates an exemplary ceramic-polymer composite capacitor 10. This embodiment of the exemplary composite capacitor 10 is constructed using a composite dielectric material 11 comprising a positive TCP (+) polymer 13 and a negative TCP (−) ceramic filler material 14. The composite capacitor 10 comprises first and second conductive electrodes 12 that sandwich the composite dielectric material 11.

For example, benzocyclobute (BCB) has a negative TCP that is close to −160 ppm/° C. By choosing an alumina filler material 141, for example, that has a positive TCP, the net TCP of the BCB-alumina composite may be tuned to be less than 10 ppm/° C. Because of the inherent low loss of both materials, the composite TCP is well within the target capacitance range for RF applications. The addition of alumina also lowers the cost of the composite. Using this approach, for example, a capacitance density of 1.6 nF/cm² with TCP<70 ppm/° C. and loss of 0.005 has been demonstrated (FIG. 1), which is believed to be the best material system ever demonstrated for RF capacitor and antenna applications.

The same concept may be extended to even higher capacitance densities with higher permittivity filler materials with positive TCP, such as tantalum oxide, alumina-titania composites, or alumina-titania composites with silicates and other glasses. For each of the filler materials, a base polymer is chosen such that its TCP compensates that of the filler material. High permittivity filler materials with negative TCP, such as titania and strontium titanate, for example, correspondingly need polymers with positive TCP such as epoxies, for example. With titanate based filler materials that have negative TCP and positive TCP polymers such as low loss epoxies/polyimides, higher permittivity and capacitance densities with lower loss and lower TCP can be achieved.

To make the dielectric material, the ceramic filler materials are first milled in a solvent that is compatible with the polymer with a suitable dispersant. The polymer is then added and milled for an additional time period before coating the film using any standard thin film coating method, such as spin coating, meniscus coating, screen printing, or curtain coating, for example.

Ceramic-Ceramic-Polymer Composite

FIG. 4 illustrates an exemplary ceramic-ceramic-polymer composite capacitor 10. This exemplary embodiment of the composite capacitor 10 is constructed using positive and negative TCP ceramic filler materials 14, 15. The composite capacitor 10 comprises first and second conductive electrodes 12 that sandwich a composite dielectric material 11. The composite dielectric material 11 comprises a polymer matrix 13 having a known positive or negative TCP and a blend of positive and negative TCP ceramic filler materials 14, 15. The ceramic filler materials 14, 15 are formulated and adjusted to compensate the positive or negative TCP of the polymer matrix 13 to achieve a TCP for the composite dielectric material 11 that is close to zero.

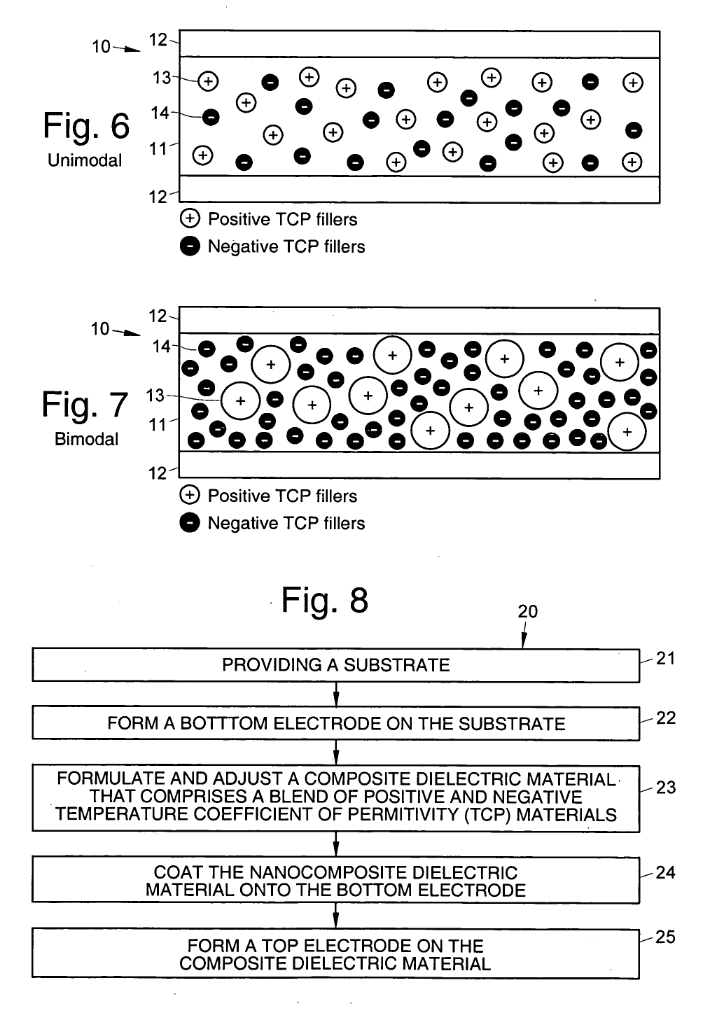

In this composite dielectric capacitor 10, the net TCP of the composite can be made close to zero while increasing the permittivity. In addition, the polymer matrix 13 provides an ideal platform for varying the packing density, which affects the dielectric properties of the capacitor 10. FIG. 6 illustrates a unimodal distribution of two ceramic filler materials (particles) 14, 15, while FIG. 7 illustrates a bimodal distribution of two ceramic filler materials (particles) 14, 15. The packing density can be easily increased using a bimodal distribution of the two ceramic filler materials (particles) 14, 15 where finer particles fill interstitial empty spaces (porosity) between coarser particles (see FIG. 7). With the disclosed approach, filler loading can be much higher and the permittivity does not have to be compromised.

Core-Shell-Polymer Composite

FIG. 5 illustrates an exemplary core-shell-polymer composite device 10 comprising a composite capacitor 10. This embodiment of the exemplary composite capacitor 10 is constructed using a composite dielectric material 11 comprising a positive or negative TCP polymer 13 and a core shell material structure 16, in which core materials have different signs of TCP with shell materials so that total TCP of core-shell is adjusted to compensate the positive or negative TCP of the polymer matrix 13 precisely. The composite capacitor 10 comprises first and second conductive electrodes 12 that sandwich the composite dielectric material 11.

In summary, the approach disclosed herein provides for a number of polymer composite material formulations for low TCP, low loss, high permittivity and permeability applications as follows.

Polymers having a positive TCP include epoxy, for example. Polymers having a negative TCP include benzocyclobute (BCB) and polyimide, for example. Other polymers having positive or negative include flame retardant woven glass reinforced epoxy resin (FR-4), liquid crystal polymer (LCP), and polycarbonate, for example.

Ceramic materials having a positive TCP include alumina, barium titanate, tantalum oxide, and barium strontium titanate, for example. Ceramic materials having a negative TCP include strontium titanate and barium strontium titanate, for example. Other ceramic materials having positive or negative include alumina-titania compound, titania, calcium magnesium, pyrochlore-based high permittivity compounds, silicate, silica based systems, lead magnesium niobates, titanates, bismuth niobates, zinc niobates, bismuth titanates, zinc titanates, glasses, and silicate/silica based systems, for example.

Formulations having two kinds of ceramic filler materials (positive TCP and negative TCP) in a polymer matrix may be used to compensate for the thermal instability of each other. Furthermore, the filler material may be a heterogeneous structure with multiple regions having compensating temperature coefficients of permittivity.

The approach described herein envisions the use of these materials in any thin or thick film capacitor, antenna or other similar electronic components for electronic applications, which are on the surface of or within an organic layer, on the surface of or in the body of silicon, on the surface of or within the body of a ceramic material, and any ceramic composite or insulating material.

For the purposes of completeness, FIG. 8 illustrates exemplary methods 20 of fabricating a composite device 10, and in particular, a composite capacitor 10. The exemplary methods 20 may be implemented as follows.

A substrate is provided 21. A bottom conductive electrode is formed 22 on the substrate. A composite dielectric material is formulated and adjusted 23. The formulated and adjusted composite dielectric material is coated 24 onto the bottom conductive electrode. A top electrode is formed 25 on the coated composite dielectric material to complete the composite device 10.

The dielectric properties of the composite capacitor 10 may be adjusted 23 by varying the packing density of the dielectric material 11. This may be achieved by using a bimodal distribution of the ceramic filler materials 13, 14, where finer particles fill interstitial empty spaces between coarser particles.

Thus, organic based dielectric materials and methods for use in fabricating miniaturized RF components have been disclosed. It is to be understood that the above-described embodiments are merely illustrative of some of the many specific embodiments that represent applications of the principles discussed above. Clearly, numerous and other arrangements can be readily devised by those skilled in the art without departing from the scope of the invention.

What is claimed is:

1. RF electronic apparatus comprising:
a composite dielectric material comprising liquid coatable composite dielectric layers that comprise a polymer material having positive or negative temperature coefficient of permittivity and one or more ceramic filler materials having a compensating temperature drift with the polymer such that the composite temperature coefficient of permittivity is lowered.

2. The apparatus recited in claim 1 wherein the negative temperature coefficient of permittivity polymer material is selected from a group including benzocyclobutene and polyimide.

3. The apparatus recited in claim 1 wherein the positive temperature coefficient of permittivity polymer material comprises epoxy.

4. The apparatus recited in claim 1 wherein the positive temperature coefficient of permittivity ceramic filler material is selected from a group including alumina, barium titanate, tantalum oxide, and barium strontium titanate.

5. The apparatus recited in claim 1 wherein the negative temperature coefficient of permittivity ceramic filler material is selected from a group including strontium titanate and barium strontium titanate.

6. The apparatus recited in claim 1 wherein the polymer comprises a polymer having positive or negative temperature coefficients of permittivity that is selected from a group including flame retardant woven glass reinforced epoxy resin (FR-4), liquid crystalline polymers (LCP), and polycarbonate.

7. The apparatus recited in claim 1 wherein the polymer comprises ceramic filler material having positive or negative temperature coefficients of permittivity that is selected from a group including alumina-titania compound, titania, calcium magnesium, pyrochlore-based high permittivity compounds, silicate, silica based systems, lead magnesium niobates, titanates, bismuth niobates, zinc niobates, bismuth titanates, zinc titanates, glasses, and silicate/silica based systems.

8. The apparatus recited in claim 1 wherein the composite dielectric material comprises a blend of positive and negative temperature coefficient of permittivity filler materials.

9. The apparatus recited in claim 1 wherein the composite dielectric material has a bimodal distribution of positive and negative temperature coefficient of permittivity filler materials.

10. The apparatus recited in claim 1 wherein the composite dielectric material comprises a thin or thick film capacitor.

11. The apparatus recited in claim 1 wherein the composite dielectric material comprises an antenna.

12. The apparatus recited in claim 1 wherein the composite dielectric material is on the surface of or within an organic layer, a silicon layer, a ceramic or ceramic composite material, or an insulating material.

13. A method of fabricating a composite RF device, comprising:
providing a substrate;
forming a bottom conductive electrode on the substrate;
formulating a composite dielectric material having a temperature coefficient, of permittivity that comprises a polymer material having positive or negative temperature coefficient of permittivity and one or more ceramic filler materials having corresponding negative or positive temperature coefficients of permittivity, which combination is adjusted so that the combined temperature coefficient of permittivity is lowered;
coating the formulated and adjusted composite material onto the bottom conductive electrode;
drying, baking and soft and hard curing of the coated composite materials; and
forming top electrode on the coated composite dielectric material to complete the composite device.

14. The method recited in claim 13 further comprising:
adjusting dielectric properties of the composite RF device by varying the packing density of the dielectric material.

15. The method recited in claim 14 wherein adjusting is achieved using a bimodal distribution of the filler materials, wherein finer particles fill interstitial empty spaces between coarser particles.

16. The method recited in claim 14 wherein ceramic filler materials are dispersed in the polymer along with additives including surfactant, dispersant and solvent.

17. The method recited in claim 13 wherein the ceramic filler is modified with dopants to compensate the temperature drift of the polymer.

18. The method recited in claim 17 wherein the dopants are selected from a group including hydroxyl groups and oxide dopants.

19. The method recited in claim 13 wherein the stoichiometry of the filler material is adjusted to modify its temperature coefficient of permittivity and compensate the temperature coefficient of permittivity of the polymer material.

20. The method recited in claim 13 wherein the filler material is a heterogeneous structure with multiple regions having compensating temperature coefficient of permittivity.

21. The method recited in claim 20 wherein the heterogeneous structure comprises a core and a shell.

22. The method recited in claim 21 wherein the core comprises barium titanate and the shell comprises strontium titanate.
